(19) United States
(12) Patent Application Publication
(10) Pub. No.: US 2015/0070553 A1
(43) Pub. Date: Mar. 12, 2015

(54) IMAGE SENSOR, IMAGE PROCESSING SYSTEM INCLUDING THE SAME, AND METHOD OF OPERATING THE SAME

(71) Applicants: Kyung Ho LEE, Suwon-si (KR); Jung Chak AHN, Yongin-si (KR); Hisanori IHARA, Seongnam-si (KR); Jun Ho YOON, Seoul (KR)

(72) Inventors: Kyung Ho LEE, Suwon-si (KR); Jung Chak AHN, Yongin-si (KR); Hisanori IHARA, Seongnam-si (KR); Jun Ho YOON, Seoul (KR)

(21) Appl. No.: 14/454,144

(22) Filed: Aug. 7, 2014

(30) Foreign Application Priority Data
Sep. 10, 2013 (KR) 10-2013-0108175

(51) Int. Cl. H04N 5/378; H04N 5/357; H04N 5/374

(52) U.S. Cl. CPC H04N 5/378; H04N 5/374; H04N 5/357
USPC 348/308

(57) ABSTRACT

A method of operating an image sensor, which includes a plurality of pixels including a photo diode that accumulates photocharges generated according to incident light, is provided. The method includes changing a potential of the photo diode by applying a hulk control signal at a first voltage level to a ground terminal, transferring the photocharges accumulated at the photo diode to a floating diffusion node, and generating a pixel signal according to a potential of the floating diffusion node.

### CROSS-REFERENCE TO RELATED APPLICATIONS

This application claims priority under 35 U.S.C. §119(a) from Korean Patent Application No. 10-2013-0108175 filed on Sep. 10, 2013, the disclosure of which is hereby incorporated by reference in its entirety.

### FIELD

Example embodiments relate to an image sensor, an image processing system including the same, and a method of operating the same, and more particularly, to an image sensor for improving image quality by reducing noise from a pixel signal and increasing a saturation electron number, an image processing system including the same, and a method of operating the same.

### BACKGROUND

Complementary metal oxide semiconductor (CMOS) image sensors are solid image pickup devices using CMOS circuits. CMOS image sensors typically have lower manufacturing cost and smaller size than charge coupled device (CCD) image sensors that have a high-voltage analog circuit. CMOS image sensors may also have lower power consumption than CCD image sensors. In addition, the performance of CMOS image sensors has been improved as compared to an early development stage, and therefore, CMOS image sensors are usually used for various electronic appliances including portable devices, such as smart phones and/or digital cameras.

Recently, there has been a demand for increasing the quality of images generated by CMOS image sensors. In particular, since various types of noise generated in elements within CMOS image sensors during operation cause the deterioration of image quality, it is desired to remove the noise and increase a saturation electron number.

### SUMMARY

At least one example embodiment relate to a method of operating an image sensor.

According to an example embodiment, a method of operating an image sensor, where the image sensor includes a plurality of pixels, each of the plurality of pixels include a corresponding photo diode and a ground terminal, and the photo diode accumulates photocharges generated according to incident light. The method includes changing, for each of the plurality of pixels, a potential of each corresponding photo diode by applying a corresponding bulk control signal at a first voltage level to each corresponding ground terminal.

Example embodiments provide that each of the plurality of pixels includes a corresponding floating diffusion node, and the method further includes transferring the photocharges accumulated at each photo diode to each corresponding floating diffusion node, and generating a pixel signal according to a potential of each corresponding floating diffusion node.

Example embodiments provide that the first voltage level is not 0V and each of the pixels is electrically isolated from adjacent pixels.

Example embodiments provide that the method may further include recovering, for each of the plurality of pixels, the potential of each corresponding photo diode by applying the corresponding bulk control signal at a second voltage level to the corresponding ground terminal.

Example embodiments provide that each of the plurality of pixels includes a corresponding floating diffusion node, and the method further includes resetting each corresponding floating diffusion node to a pixel voltage according to a corresponding reset control signal, the corresponding reset control being at a reference voltage level when a period in which the potential of each corresponding photo diode is changed.

Example embodiments provide that the changing includes applying each corresponding bulk control signal to each of the plurality of pixels, where each of the corresponding bulk control signals are at the first voltage level.

Example embodiments provide that the plurality of pixels are arranged in a matrix, the matrix including a plurality of rows and a plurality of columns, and the changing includes applying each corresponding bulk control signal to a corresponding one of the plurality of rows during a different time period, where each corresponding bulk control signal is at the first voltage level.

Example embodiments provide that the changing the potential of the photo diode includes applying a different bulk control signal to each of the plurality of pixels where each of the different bulk control signals are at the first voltage level.

Another example embodiment relates to an image sensor.

According to another example embodiment an image sensor includes a plurality of pixels. Each one of the plurality of pixels include a photo diode configured to accumulate photocharges, the photocharges being generated according to incident light, and a ground terminal configured to receive a bulk control signal at a first voltage level, the bulk control signal being used to change a potential of the photo diode.

Example embodiments provide that each one of the plurality of pixels further include a transfer transistor configured to transfer the photocharges accumulated at the photo diode to a floating diffusion node; a drive transistor configured to generate a pixel signal according to a potential of the floating diffusion node; and a deep trench isolation (DTI) region configured to electrically isolate each one of the plurality of pixels from adjacent ones of the plurality of pixels.

Example embodiments provide that the first voltage level is not 0 V.

Example embodiments provide that the ground terminal receives the bulk control signal at a second voltage level to recover the potential of the photo diode.

Example embodiments provide that the second voltage level is 0 V.

Example embodiments provide that each of the pixels further includes a reset transistor configured to reset a floating diffusion node to a pixel voltage according to a reset control signal. The reset control signal is at a reference voltage level when a period in which the bulk control signal is at the first voltage level.

Example embodiments provide that the first voltage level is a negative voltage level.

Example embodiments provide that each of the plurality of pixels receives the same bulk control signal.

Example embodiments provide that the plurality of pixels are arranged in a matrix including a plurality of rows and a plurality of columns, and each of the plurality of rows receives the bulk control signal at the first voltage level during a different time period.

Example embodiments provide that each of the pixels receives the bulk control signal at the first voltage level during a different time period.

Another example embodiment relates to an image sensor

According to another example embodiment, an image sensor includes a plurality of pixels. Each of the plurality of pixels includes a photo diode configured to accumulate photocharges generated according to incident light, and a ground terminal. The image sensor includes a row driver configured to generate a bulk control signal for each of the plurality of pixels, and transfer the bulk control signal to the ground terminal of each of the plurality of pixels. The image sensor includes a readout block configured to process a pixel signal output from each of the plurality of pixels. Each of the plurality of pixels generates the pixel signal corresponding to the photocharges accumulated at the photo diode having a potential changing according to the bulk control signal at a first voltage level.

Example embodiments provide that the first voltage level is not 0 V.

Example embodiments provide that each of the plurality of pixels further includes a deep trench isolation (DTI) region configured to electrically isolate each of the plurality of pixels from adjacent ones of the plurality of pixels.

Example embodiments provide that each pixel receives the bulk control signal at a second voltage level and recovers the potential of the photo diode and the second voltage level is 0 V.

Example embodiments provide that each of the plurality of pixels further include a floating diffusion node, and a reset transistor configured to reset the floating diffusion node to a pixel voltage according to a reset control signal, the reset control being at a reference voltage level when a period in which the bulk control signal is at the first.

Example embodiments provide that the first level is a negative voltage level.

Example embodiments provide that each of the plurality of pixels receives the same bulk control signal at the first voltage level.

Example embodiments provide that the plurality of pixels are arranged in a matrix including a plurality of rows and a plurality of columns, and each of the plurality of rows receives the bulk control signal at the first voltage level during a different time period.

Example embodiments provide that each pixel receives the bulk control signal at the first voltage level during a different time period.

At least one example embodiment relates to an image processing system.

According to another example embodiment, an image processing system is provided. The image processing system includes an image sensor including a plurality of pixels. Each of the plurality of pixels including a photo diode configured to accumulate photocharges generated according to incident light, and read out a pixel signal that is output from each of the plurality of pixels. Each of the plurality of pixels includes a ground terminal configured to receive a bulk control signal at a first voltage level to change a potential of the photo diode, a transfer transistor configured to transfer the photocharges accumulated at the photo diode to a floating diffusion node, and a drive transistor configured to generate the pixel signal according to a potential of the floating diffusion node. The image processing system includes an image signal processor configured to process the pixel signal, and generate image data

### BRIEF DESCRIPTION OF THE DRAWINGS

The above and other features and advantages of the example embodiments will become more apparent by describing in detail exemplary embodiments thereof with reference to the attached drawings in which:

FIG. 1 is a block diagram of an image processing system including an image sensor according to an example embodiment;

FIG. 2 is a block diagram of a pixel array and a row driver illustrated in FIG. 1, according to an example embodiment;

FIG. 3 is a block diagram of the pixel array and the row driver illustrated in FIG. 1, according to an example embodiment;

FIG. 4 is a block diagram of the pixel array and the row driver illustrated in FIG. 1, according to an example embodiment;

FIG. 5A is a diagram of a pixel illustrated in FIGS. 2 through 4, according to an example embodiment;

FIG. 5B is a diagram of a pixel illustrated in FIGS. 2 through 4, according to an example embodiment;

FIG. 5C is a diagram of a pixel illustrated in FIGS. 2 through 4, according to an example embodiment;

FIG. 6 is a block diagram of a layout of a pixel illustrated in FIG. 5A, according to an example embodiment;

FIG. 7 is a cross-sectional view of the layout illustrated in FIG. 6, according to an ex ample embodiment;

FIG. 8 is a timing chart of control signals applied to the pixel illustrated in FIG. 5A, according to an example embodiment;

FIG. 9 is a timing chart of control signals applied to the pixel illustrated in FIG. 5A, according to an example embodiment;

FIGS. 10 through 13 are diagrams of potential distributions in elements of a pixel according to the control signals illustrated in FIGS. 8 and 9, according to an example embodiment;

FIG. 14 is a flowchart of a method of operating an image sensor, according to an example embodiment; and

FIG. 15 is a flowchart of a method of operating an image sensor, according to an example embodiment.

### DETAILED DESCRIPTION OF THE EMBODIMENTS

The example embodiments now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. Like numbers refer to like elements throughout.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein, the term “and/or” includes any and all combinations of one or more of the associated listed items and may be abbreviated as “/”.

It will be understood that, although the terms first, second, etc. may be used herein to describe various elements, these elements should not be limited by these terms. These terms are only used to distinguish one element from another. For example, a first signal could be termed a second signal, and, similarly, a second signal could be termed a first signal without departing from the teachings of the disclosure.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

Example embodiments provide an image sensor for reducing noise in the characteristics of a pixel and more particularly in a pixel signal and improving a saturation electron number by securing a voltage margin between a photo diode and a floating diffusion by adjusting the potential of a body (or bulk) in a pixel, an image processing system including the same, and a method of operating the same.

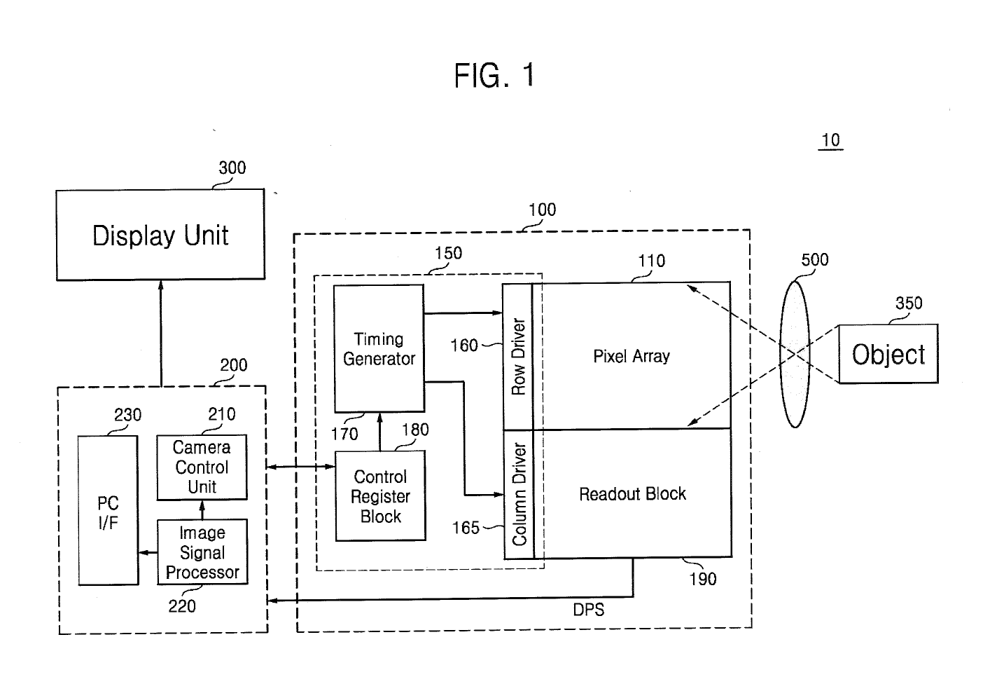

FIG. 1 is a block diagram of an image processing system 10 including an image sensor 100 according to an example embodiment. The image processing system 10 includes the image sensor 100, a digital signal processor (DSP) 200, a display unit 300, and a lens 500. The image sensor 100 includes a pixel array 110, a control unit 150, and a readout block 190.

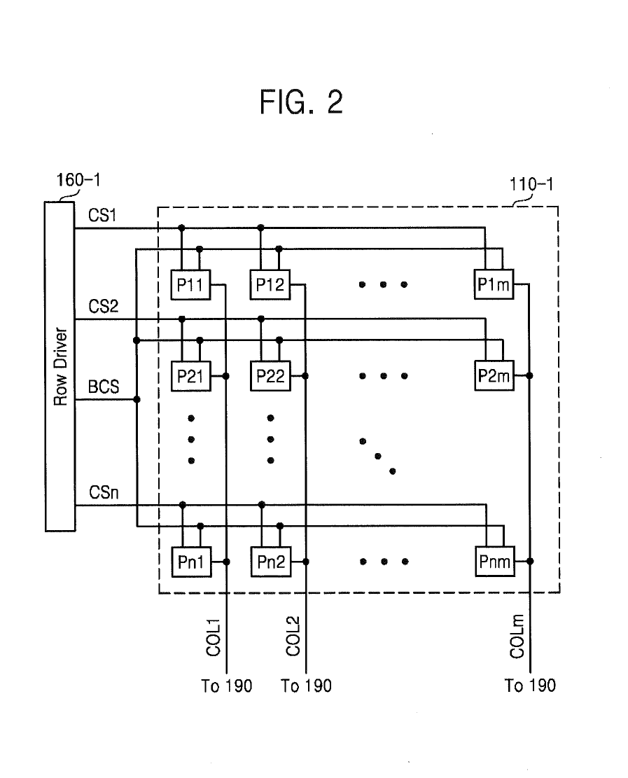

The pixel array 110 may include a plurality of pixels (e.g., P11 through Pnm as shown in FIG. 2), each of which accumulates photocharges generated in response to incident light and generates a pixel signal corresponding to the photocharges. Each pixel includes a plurality of transistors and a photoelectric conversion element such as a photo diode or a pinned photo diode. The pixel array 110 senses light using a plurality of photoelectric conversion elements and converts the light into electrical signals, thereby generating pixel signals.

The control unit 150 may generate and provide a plurality of control signals for controlling the operations of the pixel array 110 and the readout block 190. The control unit 150 may include a row driver 160, a column driver 165, a timing generator 170, and a control register block 180.

The row driver 160 drives the pixel array 110 in row units. In various embodiments, pixels in one row may be provided with the same control signal (e.g., one of CS1 through CSn as shown in FIG. 2). In various embodiments, the row driver 160 may provide a bulk control signal (e.g., BCS in FIG. 2) for the pixels included in the pixel array 110. In such embodiments, the row driver 160 may decode a control signal output from the timing generator 170 and provide control signals for the pixel array 110.

The column driver 165 may generate a plurality of control signals according to the control of the timing generator 170 and may control the operation of the readout block 190.

The timing generator 170 may apply a control signal and/or a clock signal to the row driver 160 and the column driver 165. The control signal and/or clock signal is used to control the operations and/or timing of the row driver 160 and the column driver 165. The timing generator 170 may generate the control signal and/or the clock signal to be applied to the row driver 160 and the column driver 165 using a control signal and a clock signal received from an external device (e.g., a host). The control register block 180 operates according to the control of a camera control unit 210 and may store and/or buffer the control signal and/or the clock signal.

The readout block 190 may perform analog-to digital conversion on pixel signals generated by the respective pixels, temporarily store the converted pixel signals, and amplify the converted pixel signals to output a digital pixel signal DPS.

The DSP 200 may generate image data by processing the digital pixel signal DPS output from the image sensor 100 and output the image data to the display unit 300. The DSP 200 includes the camera control unit 210, an image signal processor (ISP) 220, and a personal computer interface (PC I/F) 230.

The camera control unit 210 controls the control register block 180. The camera control unit 210 may control the control register block 180 using an inter-integrated circuit (I²C), but the scope of the example embodiments is not restricted thereto, and the camera control unit 210 may control the control register block 180 using any multimaster bus or other like device for attaching or otherwise associating a peripheral device with a motherboard, embedded system, mobile terminal, or other like electronic device.

The ISP 220 processes the digital pixel signal DPS output from the readout block 190 into image data and outputs the image data to the display unit 300 through the PC I/F 230. In various embodiments, the ISP 220 is implemented in a chip separated from the image sensor 100. In some embodiments, the ISP 220 and the image sensor 100 may be integrated into a single chip.

The display unit 300 may be any device that can output an image or otherwise present image data in a visual or tactile form. For instance, the display unit 300 may be implemented as a computer monitor, a mobile phone screen and/or a smart phone screen, a head mounted display device, or any type of image output device. The image output devices may employ any electronic visual display technology, such as a liquid crystal (LCD) display, a light-emitting diode (LED) display, organic LED (OLED) display, electroluminescent (ELD) display, and/or other like display electronic visual display technology.

FIG. 2 is a block diagram of pixel array 110-1 and row driver 160-1 of the pixel array 110 and the row driver 160 illustrated in FIG. 1, according to an example embodiment. Referring to FIGS. 1 and 2, the pixel array 110-1 includes a plurality of pixels P11 through Pnm arranged in a matrix of “n” rows and “m” columns.

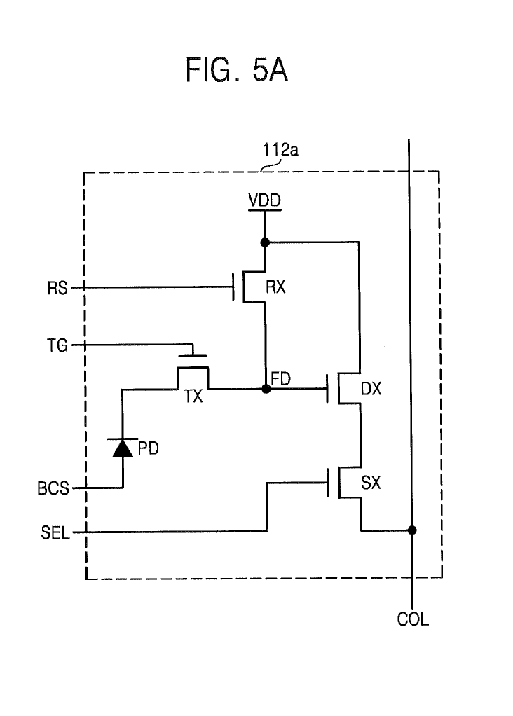

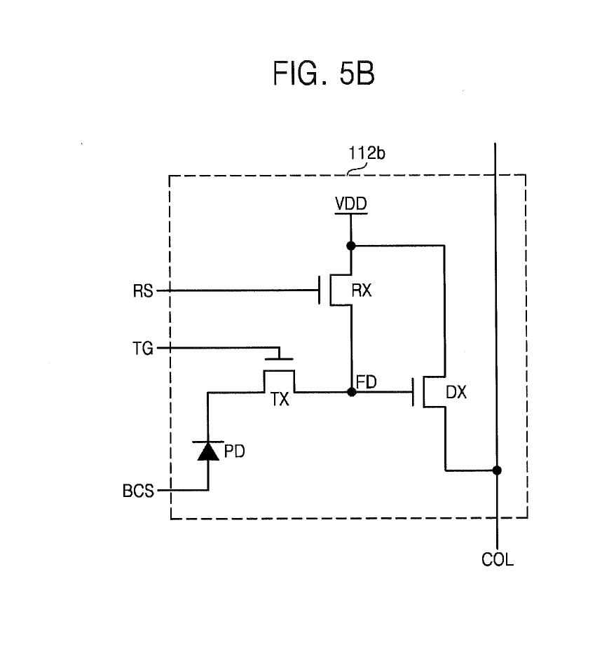

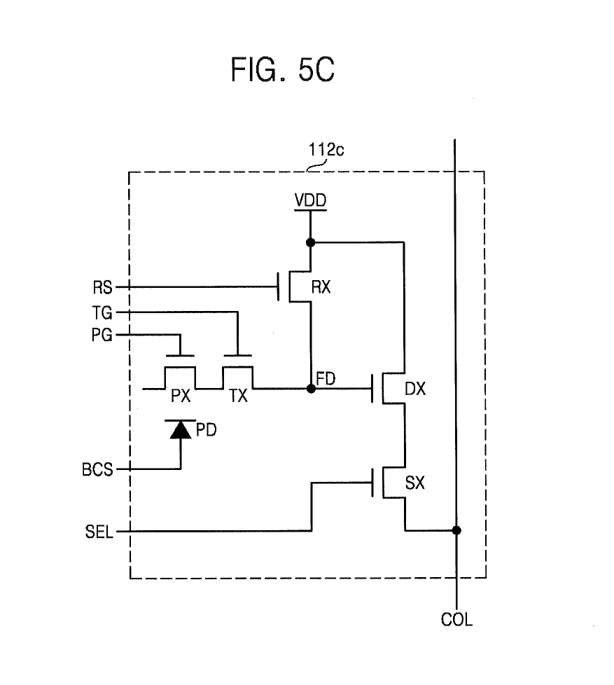

Among the pixels P11 through Pnm, pixels in one row receive the same control signal (i.e., one of control signals CS1 through CSn). Each of the control signals CS1 through CSn includes signals (e.g., TG, RS, and SEL as shown in FIG. 5A) for controlling transistors (e.g., TX, RX, and SX as shown in FIG. 5A) included in each of the pixels P11 through Pnm.

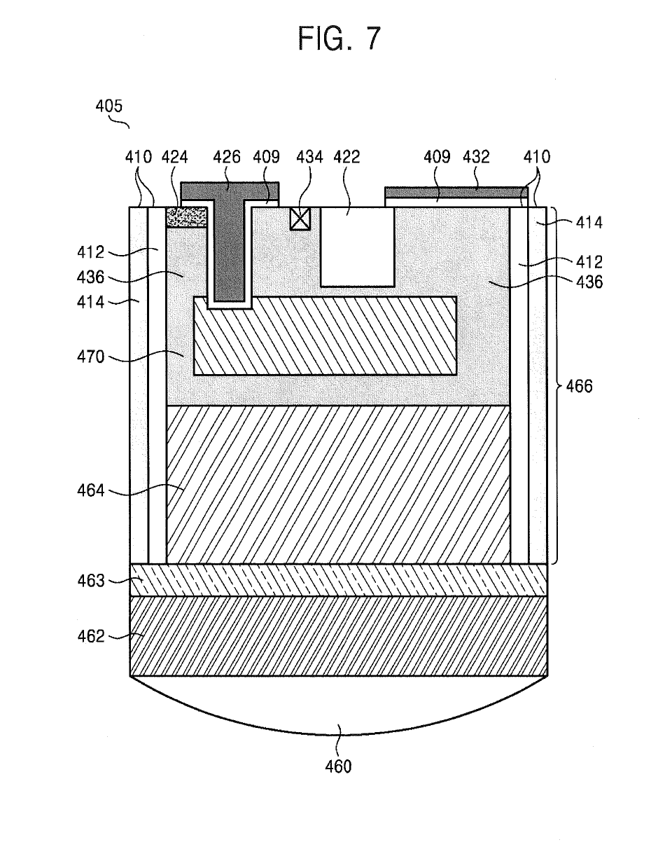

The pixels P11 through Pnm receive the same bulk control signal BCS. The bulk control signal BCS is applied to a p-well region (436 as shown in FIG. 7) through a terminal (e.g., ground terminal 434 as shown in FIG. 7) of a photo diode (e.g., PD as shown in FIG. 5A). The p-well region 436 is called a bulk that may be connected in common to a photo diode 470 and to the body of transistors in all of the pixels P11 through Pnm. Each of the pixels P11 through Prim may output a pixel signal to one of column lines COL1 through COLm.

The bulk control signal BCS may be at 0 V or various voltage levels. A threshold voltage of a transfer transistor (e.g., TX as shown in FIG. 5A) included in each of the pixels P11 through Pnm may be changed according to the level of the bulk control signal BCS. The threshold voltage of the transfer transistor in each of the pixels P11 through Pnm is higher when the bulk control signal BCS at a negative level is applied to the pixels P11 through Pnm than when the bulk control signal BCS at 0 V is applied to the pixels P11 through Pnm. Contrarily, the threshold voltage is lower when the bulk control signal BCS at a positive level is applied to the pixels P11 through Pnm than when the bulk control signal BCS at 0 V is applied to the pixels P11 through Pnm.

When the threshold voltage increases due to the bulk control signal BCS at the negative level being applied to the pixels P11 through Pnm, the potential of a gate of the transfer transistor decreases and a full well capacity (FWC) increases. When the threshold voltage decreases due to the bulk control signal BCS at the positive level being applied to the pixels P11 through Pnm, the potential of the gate of the transfer transistor increases and the FWC decreases. The FWC indicates the number of photocharges that can be accumulated in a photo diode. The higher the FWC, a pixel has better signal-to-white-noise ratio and dynamic range.

The threshold voltage is also related with a blooming effect in which transfer of photocharges from a pixel to other adjacent pixels causes noise. The blooming effect may increase when the potential of the gate of the transfer transistor decreases.

When the threshold voltage increases clue to the bulk control signal BCS at the negative level being applied to the pixels P11 through Pnm, the potential of the gate of the transfer transistor decreases and the blooming effect increases. When the threshold voltage decreases due to the bulk control signal BCS at the positive level being applied to the pixels P11 through Pnm, the potential of the gate of the transfer transistor increases and the blooming effect decreases.

Accordingly, the threshold voltage of the transfer transistor is controlled by controlling the level of the bulk control signal BCS, and the FWC and blooming effect of the pixels P11 through Pnm are controlled. Since the FWC and the blooming effect are in a trade-off relationship, the levels of the bulk control signal BCS should be appropriately selected.

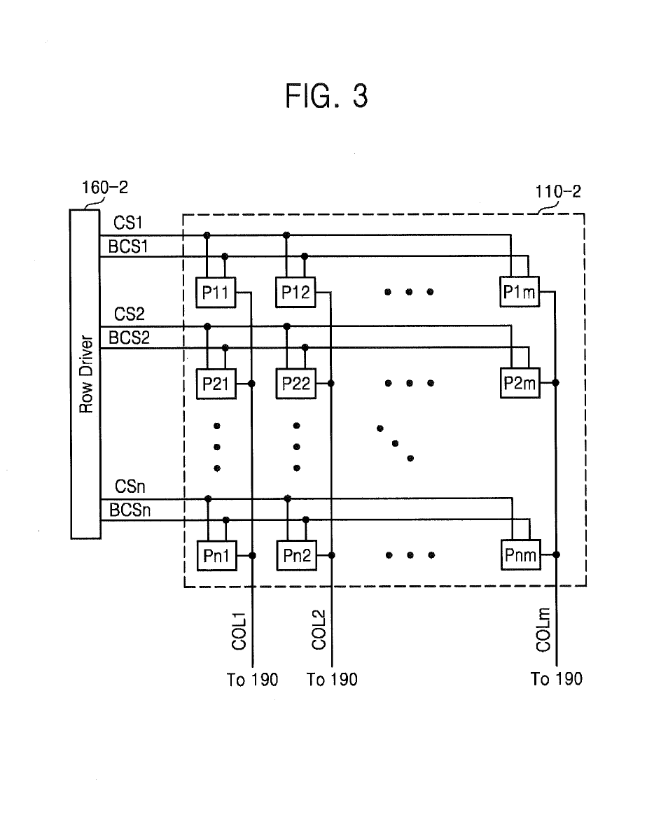

FIG. 3 is a block diagram of pixel array 110-2 and row driver 160-2 of the pixel array 110 and the row driver 160 illustrated in FIG. 1, according to an example embodiment. Referring to FIGS. 1 through 3, pixels in one row among the pixels P11 through Pnm receive the same bulk control signal (i.e., one of bulk control signals BCS1 through BCSn). Accordingly, the threshold voltage of the transfer transistor included in each of the pixels in one row among the pixels P11 through Pnm can be controlled by one of the bulk control signals BCS1 through BCSn.

In some instances, because of an error in a photolithography process during the manufacturing of the pixel array 110, Gr/Gb color difference may occur. The Gr/Gb color difference is the color difference between green pixels Gr and Gb respectively belonging to different rows among pixels arranged in a bayer pattern. The Gr/Gb color difference is caused by the difference in threshold voltage between transfer transistors of the respective green pixels Gr and Gb belonging to adjacent rows, respectively.

In order to reduce or otherwise eliminate the Gr/Gb color difference, the different bulk control signals BCS1 through BCSn may be applied to corresponding rows of the pixel array 110-2. For instance, the bulk control signal BCS1 at a positive level may be applied to the pixels P11 through Pim in the first row, and the bulk control signal BCS2 at a negative level may be applied to the pixels P21 through P2m in the second row. In the same manner, the bulk control signals BCS3 through BCSn alternately at the positive level and the negative level may be applied to the third through n-th rows, respectively.

The threshold voltage of the transfer transistor of pixels in each of the rows may be controlled according to one of the bulk control signals BCS1 through BCSn applied to its corresponding row. When the threshold voltage is changed according to the control, the FWC or the efficiency of photocharge transfer to a floating diffusion may be changed. When the threshold voltages of transfer transistors of green pixels Gr and Gb belonging to adjacent rows, respectively, are controlled by applying the bulk control signals BCS1 through BCSn at different levels to the corresponding rows, the Gr/Gb color difference can be reduced or otherwise eliminated.

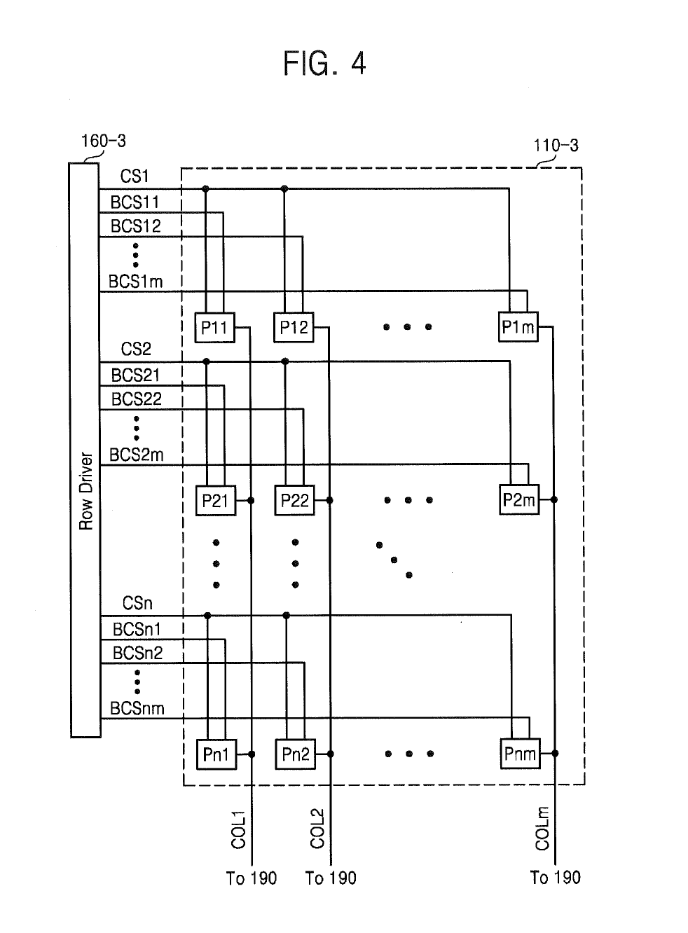

FIG. 4 is a block diagram of pixel array 110-3 and row driver 160-3 of the pixel array 110 and the row driver 160 illustrated in FIG. 1, according to an example embodiment. Referring to FIGS. 1 through 4, the pixels P11 through Pnm receive a corresponding one of the bulk control signals BCS11 through BCSnm, respectively. The bulk control signals BCS11 through BCSnm may be at the same voltage level or different voltage levels. Accordingly, the threshold voltage of a transfer transistor included in each of the pixels P11 through Pnm may be controlled by one of the bulk control signals BCS11 through BCSnm. In various embodiments, the threshold voltage of the transfer transistor included in each of the pixels P11 through Pnm is independently controlled from one another, so that the characteristics of pixels related to the FWC can be individually controlled.

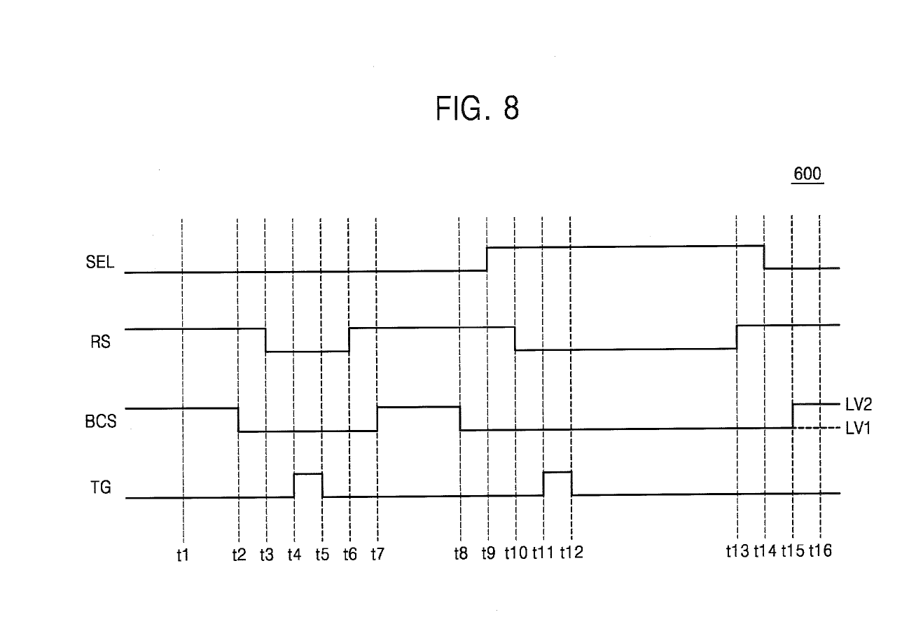

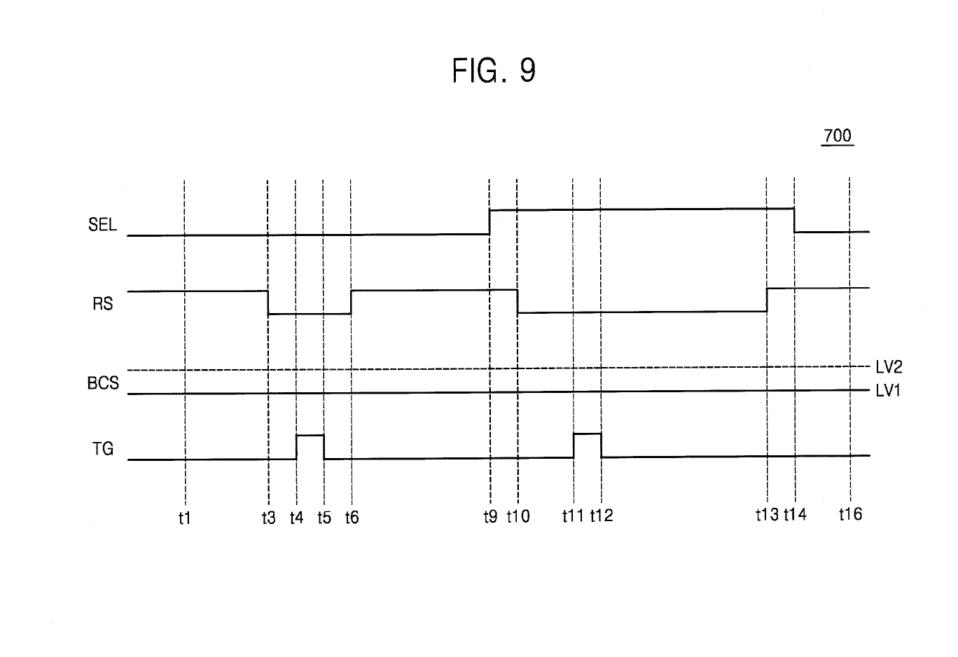

The level of bulk control signals described with reference to FIGS. 2 through 4 may be a first level LV1 or a second level LV2, as illustrated in FIGS. 8 and 9.

FIG. 5A is a diagram of pixel 112a of the pixels P11 through Pnm illustrated in FIGS. 2 through 4, according to an example embodiment. FIG. 5B is a diagram of pixel 112b of the pixels P11 through Pnm illustrated in FIGS. 2 through 4, according to an example embodiment. FIG. 5C is a diagram of pixel 112c of the pixels P11 through Pnm illustrated in FIGS. 2 through 4, according to an example embodiment.

Referring to FIGS. 1 through 5C, the pixel 112a may include a photo diode PD, a transfer transistor TX, a floating diffusion node FD, a reset transistor RX, a drive transistor DX, and a select transistor SX.

FIG. 5A shows a four-transistor (4T) structure that includes a single photo diode PD and four metal oxide semiconductor (MOS) transistors TX, RX, DX, and SX, but the example embodiments are not restricted to the embodiment as shown in FIG. 5A. The example embodiments may be applied to any circuits including at least three transistors and the photo diode PD. The photo diode PD is an example of a photoelectric conversion element and may include at least one among a photo transistor, a photo gate, a pinned photo diode (PPD), and a combination thereof.

In operation of the pixel 112a, the photo diode PD generates photocharges varying with the intensity of light received from an object 350. A first terminal of the photo diode PD is connected to the transfer transistor TX and a second terminal of the photo diode PD receives the bulk control signal BCS from the row driver 160. The bulk control signal BCS is illustrated in FIG. 5A assuming that the pixel 112a is part of the pixel array 110-1 illustrated in FIG. 2, but the example embodiments are not restricted thereto.

The transfer transistor TX may transfer the photocharges to the floating diffusion node FD according to the transfer control signal TG received from the row driver 160. The drive transistor DX may amplify and transfer the photocharges to the select transistor SX according to the potential of the photocharges accumulated at the floating diffusion node FD.

The select transistor SX has a drain terminal connected to a source terminal of the drive transistor DX. The select transistor SX may output a pixel signal to a column line COL connected to the pixel 112a according to the selection control signal SEL received from the row driver 160.

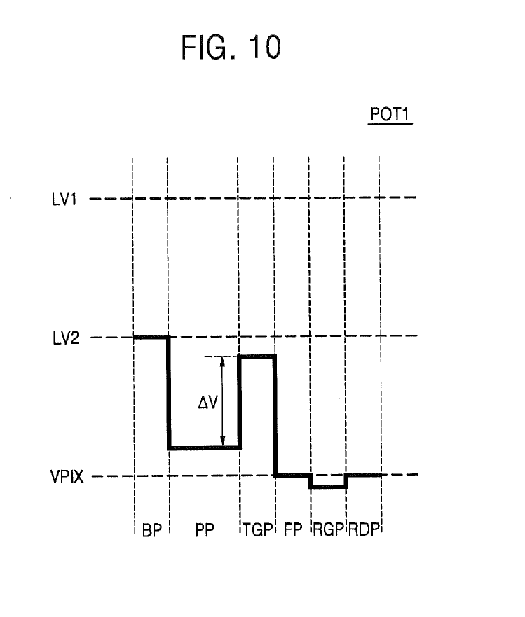

The reset transistor RX may reset the floating diffusion node FD to a pixel voltage (VPIX in FIGS. 10 through 13) according to the reset control signal RX received from the row driver 160. The pixel voltage VPIX is a driving voltage of the pixel array 110 and may be in a range of, for example, 2 to 5 V.

The pixel 112b illustrated in FIG. 5B has a three-transistor (3T) structure and may include the photo diode PD, the transfer transistor TX, the reset transistor RX, and the drive transistor DX. The reset transistor RX may be implemented as an n-channel depletion type transistor. The reset transistor RX may reset the floating diffusion node FD to the pixel voltage VPIX or to a low level and/or a reference voltage level (e.g., 0 V) to perform a similar function to the select transistor SX according to the reset control signal RX received from the row driver 160.

The pixel 112c illustrated in FIG. 5C has a five-transistor (5T) structure and may include the photo diode PD, the transfer transistor TX, the reset transistor RX, the drive transistor DX, the select transistor SX, and one more transistor PX.

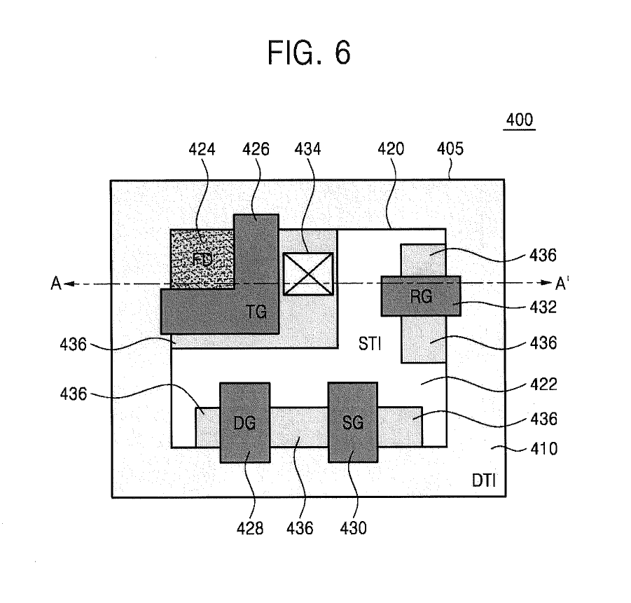

FIG. 6 is a block diagram of a layout 400 of the pixel 112a illustrated in FIG. 5A, according to an example embodiment. FIG. 7 is a cross-sectional view of the layout 400 illustrated in FIG. 6, according to an example embodiment.

Referring to FIGS. 5A, 6, and 7, the layout 400 shows an example of disposition of elements included in a pixel 405. The pixel 405 may be included in the pixel array 110 illustrated in FIG. 1, which is arranged in an m×n matrix (where “m” and “n” are natural numbers that are greater than or equal to 2).

The layout 400 may include a deep trench isolation (DTI) region 410 and an active region 420. The DTI region 410 may be formed to prevent electrical crosstalk or optical crosstalk between the pixel 405 and adjacent pixels (not shown).

The active region 420 may include a shallow trench isolation (STI) 422, a floating diffusion 424, a transfer transistor gate 426, a drive transistor gate 428, a select transistor gate 430, a rest transistor gate 432, a ground terminal 434, and a p-well region 436. Although FIG. 6 shows the layout of a pixel having the 4T structure illustrated in FIG. 5A, the example embodiments are not restricted to the embodiment illustrated by FIG. 6, and according to various embodiments, the layout shown in FIG. 6 may be applied to pixels having different structures, such as a 3T structure, a 5T structure, and the like. In addition, the disposition of elements in the active region 420 is not restricted to the embodiments illustrated in FIG. 6 and may be modified in various ways.

The STI 422 may be formed around the floating diffusion 424, the transfer transistor gate 426, the drive transistor gate 428, the select transistor gate 430, the reset transistor gate 432, the ground terminal 434, and the p-well region 436 inside the DTI area 410. The STI 422 may be formed using an STI process to electrically isolate the elements from one another. The STI 422 may be shallower than the DTI area 410.

The floating diffusion 424 may be formed adjacent to and/or close to the transfer transistor gate 426. The floating diffusion 424 corresponds to the floating diffusion node FD illustrated in FIGS. 5A through 5C and is a node which photocharges generated by the photo diode PD are transmitted to through the transfer transistor TX. The respective gates 426, 428, 430, and 432 of the transfer transistor TX, the drive transistor DX, the select transistor SX, and the reset transistor RX may receive a control signal or may be connected to the floating diffusion node FD, as described above with reference to FIGS. 5A through 5C.

The ground terminal 434 may receive a bulk control signal (e.g., BCS in FIG. 2) from the row driver 160 and may apply a voltage corresponding to the bulk control signal to the p-well region 436.

The p-well region 436 may be formed around the ground terminal 434, the drive transistor gate 428, the select transistor gate 430, and the reset transistor gate 432. A region (not shown) doped with n++ impurities may be formed in the p-well region 436. The n++-doped region may function as a source or drain terminal of the drive transistor DX, the select transistor SX, and the reset transistor RX. The p-well region 436 may electrically isolate the n++-doped region.

The p-well region 436 is called a bulk and its voltage level may be changed according to a voltage corresponding to the bulk control signal applied to the ground terminal 434. As is described with reference to FIG. 8, the changed voltage level of the p-well region 436 may influence the potential of the photo diode 470 and the transfer transistor gate 426.

FIG. 7 is a vertical cross-sectional view of the pixel 405 taken along the vertical line A-A′ illustrated in FIG. 6, according to an example embodiment. The pixel 405 may be formed by staking a micro lens 460, a color filter 462, an anti-reflection layer 463, and a semiconductor substrate 466. The semiconductor substrate 466 may include the DTI area 410, an epitaxial layer 464, a photo diode 470, the p-well region 436, the STI 422, the reset transistor gate 432, the transfer transistor gate 426, the ground terminal 434, and the floating diffusion 424. In the example embodiment illustrated in FIG. 7, it is assumed that light reflected from an object is incident from the bottom and the transistors included in the pixel 405 are n-channel MOS (NMOS) transistors. In other embodiments, the transistor may be p-channel MOS (PMOS) transistors.

According to various embodiments, the micro lens 460 may be placed at the bottom of the pixel 405 to increase light gathering power, thereby increasing the quality of images. The color filter 462 may be placed on the micro lens 460 to selectively transmit light with a predetermined wavelength (e.g., red, green, blue, magenta, yellow, or cyan). In other embodiments, a planarization layer (not shown) called an over-coating layer may be formed below the color filter 462.

The anti-reflection layer 463 may be formed on the color filter 462 to prevent light incident through the micro lens 460 and the color filter 462 from being reflected. In various embodiments, the anti-reflection layer 463 transmits incident light, thereby increasing the performance (e.g., light guiding efficiency and photo sensitivity) of an image sensor.

The DTI area 410 may prevent electric crosstalk and optical crosstalk between the pixel 405 and adjacent pixels (not shown). The DTI area 410 may include oxide 412 and/or poly silicon 414 for an electric/optical isolation from the adjacent pixels. The epitaxial layer 464 may be a p-type epitaxial layer formed on a p-type silicon substrate.

The photo diode 470 may be formed as an n-type region by performing ion implantation in the p-well region 436. According to various embodiments, the photo diode 470 may be formed of a plurality of doped regions in a stack structure. In such embodiments, an upper doped region may be formed by implanting n+-type ions and a lower doped region may be formed by implanting n−-type ions. The photo diode 470 may be formed across most of the area of the pixel 405 except for the DTI area 410 in order to obtain a high fill factor. The fill factor may be defined as a ratio of a light receiving area to the entire area of a pixel. The higher the fill factor, the higher the light guiding efficiency.

The p-well region 436 may be formed to surround the photo diode 470 to electrically isolate the photo diode 470 from the transistors. The n++-doped region close to the gates 428, 430, and 432 may function as the source or drain terminal of each transistor. Multi-layer conductive lines (not shown) may be formed on the semiconductor substrate 466. The multi-layer conductive lines may be formed by patterning conductive materials including metals such as copper and aluminum.

The STI 422 may be formed to electrically isolate adjacent elements of the pixel 405. The reset transistor gate 432 and the transfer transistor gate 426 may be formed on corresponding parts, respectively, of a gate isolation layer 409. The gate isolation layer 409 may be formed of SiO2, SiON, SiN, Al2O3, Si3N4, GexOyNz, GexSiyOz, or one or more high dielectric materials. The high dielectric material may be formed by performing atomic layer deposition of HfO2, ZrO2, Al2O3, Ta2O5, hafnium silicate, zirconium silicate, or any combination thereof.

In particular, the transfer transistor gate 426 may be formed using a trench process when the photo diode 470 is formed at the center of the semiconductor substrate 466. According to various embodiments, the transfer transistor gate 426 may be formed to be above or below the top surface of the photo diode 470. The floating diffusion 424 may be formed close to the transfer transistor gate 426. The floating diffusion 424 may be electrically isolated from the photo diode 470 by the p-well region 436 formed between the floating diffusion 424 and the photo diode 470.

The DTI area 410 may be formed using a trench process. The trench process includes forming a trench to a desired depth in the semiconductor substrate 466. The trench process may be at least one of a DTI process of forming a relatively deep trench and an STI process of forming a relatively shallow trench. The pixel 405 is electrically isolated by the DTI region 410 from adjacent pixels (not shown) and a bulk (i.e., the p-well region 436 in each pixel is isolated by the DTI region 410). Therefore, the bulk included in each pixel can be independently controlled by a bulk control signal (e.g., BCS) applied to the ground terminal 434.

FIG. 8 is a timing chart of control signals applied to the pixel 112a illustrated in FIG. 5A according to an example embodiment. FIG. 9 is a timing chart of control signals applied to the pixel 112a illustrated in FIG. 5A according to an example embodiment.

Referring to FIGS. 5A, 8, and 9, FIG. 8 shows an example 600 of the selection control signal SEL, the reset control signal RS, the bulk control signal BCS, and the transfer control signal TG, which are applied to the pixel 112a illustrated in FIG. 5A. Although the control signals SEL, RS, BCS, and TG applied to the pixel 112a illustrated in FIG. 5A are illustrated in FIG. 8, the example embodiments are not restricted to the example embodiment shown in FIG. 8.

A single frame may be defined as a time taken for a pixel signal of every pixel included in the pixel array 110 to be generated and output. In various embodiments, it is assumed that a time from time point t1 to time point t16 is a single frame in the example embodiments illustrated in FIGS. 8 and 9.

The selection control signal SEL is at a high level in a period from time point t9 to time point t14 during which readout is performed on a row that includes the pixel 112a. The reset control signal RS is at a high level in a period from time point t1 to time point t3, a period from time point t6 to time point t10, and a period from time point t13 to time point t16. While the reset control signal RS is at the high level, the reset transistor RX is turned on, and thus, the floating diffusion node FD is reset (or fixed) to the pixel voltage VPIX.

The transfer control signal TG is at a high level in a period from time point t4 to time point t5 and a period from time point t11 to time point t12. While the transfer control signal TG is at the high level, the transfer transistor TX is turned on, and thus, photocharges accumulated at the photo diode PD are transferred to the floating diffusion node FD. In various embodiments, while the reset control signal RS is at a low level and/or a reference voltage level, the reset transistor RX is turned off and the floating diffusion node FD is in a floating state in which a potential varies with ambient influence. When the transfer control signal TG is at the high level during the period from time point t4 to time point t5, the transfer transistor TX transfer photocharges remaining in the photo diode PD to the floating diffusion node FD. Accordingly, the photo diode PD starts to accumulate newly generated photocharges from time point t5.

When the reset control signal RS is at the high level during the period from time point to to time point t10, the reset transistor RX is turned on and resets the floating diffusion node FD. When the reset control signal RS transits to the low level and/or the reference voltage level after time point t10, the floating diffusion node FD enters the floating state again.

When the transfer control signal TG is at the high level from time point t11 to time point t12, the transfer transistor TX transfers photocharges accumulated at the photo diode PD to the floating diffusion node FD. The potential of the floating diffusion node FD in the floating state varies with the amount of the photocharges and the drive transistor DX and the select transistor SX may output a pixel signal to the column line COL according to the potential.

The bulk control signal BCS may have at least two levels. The first level LV1 may be a negative voltage level (e.g., −1 V and the like) and the second level LV2 may be a usual ground voltage level (e.g., 0 V and the like). The bulk control signal BCS may be at the first level LV1 in a period from time point t2 to time point t7 and a period from time point t8 to time point t15 and may be the second level LV2 in the other periods.

A period in which the bulk control signal BCS is at the first level LV1 includes a period in which the reset control signal RS is at the low level and/or reference voltage level. In various embodiments, the period in which the reset control signal RS is at the low level and/or reference voltage level may at least be started after the period in which the bulk control signal BCS is at the first level LV1 is started to maximize the difference between a potential (PP in FIGS. 10 through 13) of the photo diode PD and a potential (FP in FIGS. 10 through 13) of the floating diffusion node FD, which will be described with reference to FIGS. 10 through 13 later.

FIG. 9 shows another example 700 of the selection control signal SEL, the reset control signal RS, the bulk control signal BCS, and the transfer control signal TG, which are applied to the pixel 112a illustrated in FIG. 5A, according to an example embodiment. According to the example embodiment shown in the example 600 of in FIG. 8, the bulk control signal BCS may be at the second level LV2 during most of, or during an entire time, as shown in the example 700 shown in FIG. 9.

The timing of the bulk control signal BCS may be freely changed as long as a period of the first level LV1 of the bulk control signal BCS includes a period of the low level and/or reference voltage level of the reset control signal RS.

FIGS. 10 through 13 are diagrams of potential distributions in elements of a pixel according to the control signals illustrated in FIGS. 8 and 9, according to an example embodiment. Referring to FIG. 5A and FIGS. 8 through 13, FIGS. 10 through 13 show a bulk potential BP, a photo diode potential PP, a transfer transistor gate potential TGP, a floating diffusion node potential FP, a reset transistor gate potential RGP, and a reset transistor drain potential RDP, which change according to the selection control signal SEL, the reset control signal RS, the bulk control signal BCS, and the transfer control signal TG, which are applied to the pixel 112a. In FIGS. 10 through 13, a potential along a vertical direction (i.e., a voltage level becomes negative when it goes up and becomes positive when it goes down).

FIG. 10 shows a first potential distribution POT1, according to an example embodiment. As shown in FIG. 10, when the bulk control signal BCS is at the second level V2, the transfer control signal TG is at the low level and/or reference voltage level, and the reset control signal RS is at the high level. In various embodiments, the first potential distribution POT1 shows a potential distribution in a period between time points t1 and t2, a period between time points t7 and t, and a period between time points t15 and t16.

The bulk potential BP is at the second level LV2 since the bulk control signal BCS is at the second level LV2. The transfer transistor gate potential TGP is at a level slightly higher than the second level LV2 since the transfer control signal TG is at the low level and/or the reference voltage level.

The photo diode potential PP is set to be higher than the transfer transistor gate potential TGP by a pinning potential ΔV according to the hulk potential BP and the transfer transistor gate potential TGP. The pinning potential ΔV is a factor deciding the FWC. In the first potential distribution POT1, photocharges within a range of the pinning potential ΔV among photocharges generated in the photo diode PD are accumulated at the photo diode PD.

The reset transistor drain potential RDP is set to the level of the pixel voltage VPIX since the drain of the reset transistor RX is provided with the pixel voltage VPIX, as shown in FIG. 5A. The reset transistor gate potential RGP is at a slightly higher level than the pixel voltage VPIX since the reset control signal RS is at the high level. The floating diffusion node potential FP is set to the pixel voltage VPIX since the reset transistor RX is turned on.

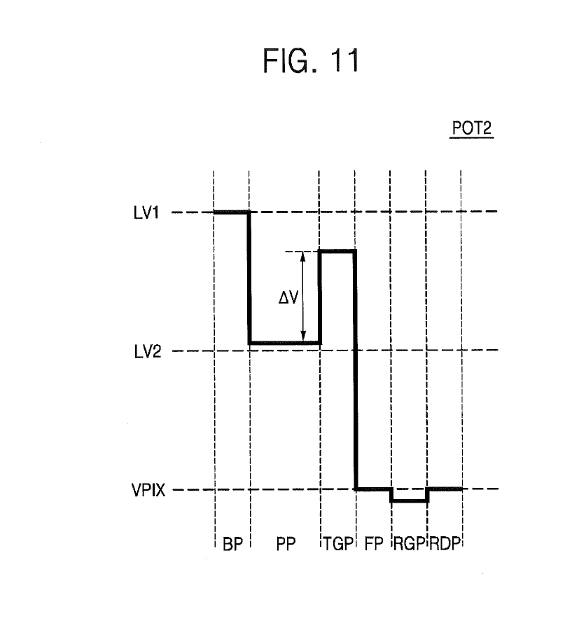

FIG. 11 shows a second potential distribution POT2, according to an example embodiment. As shown in FIG. 11, when the bulk control signal BCS is at the first level LV1, the transfer control signal TG is at the low level and/or the reference voltage level, and the reset control signal RS is at the high level. In various embodiments, the second potential distribution POT2 shows a potential distribution in periods between time points t2 and t3, between time points t6 and t7, between time points t8 and t10, and between time points t13 and t15 in FIG. 8 and periods between time points t1 and t3, between time points t6 and t10, and between time points t13 and t16 in FIG. 9.

The bulk potential BP is at the first level LV1 since the bulk control signal BCS transits to the first level LV1. The transfer transistor gate potential TGP is at a level slightly higher than the first level LV1 since the transfer control signal TG is at the low level and/or the reference voltage level.

Since the bulk potential BP decreases and the difference between the photo diode potential PP and the bulk potential BP is maintained, the photo diode potential PP decreases as much as the change in the bulk potential BP.

The floating diffusion node potential FP, the reset transistor gate potential RGP, and the reset transistor drain potential RDP remain the same as the first potential distribution POT1. Therefore, since the photo diode potential PP decreases while the floating diffusion node potential FP remains the same, the difference between the photo diode potential PP and the floating diffusion node potential FP increases. As a result, the efficiency of photocharge transfer from the photo diode PD to the floating diffusion node FD increases as compared to when the difference between the photo diode potential PP and the floating diffusion node potential FP is smaller, and also photocharge back flow from the floating diffusion node FD to the photo diode PD is prevented.

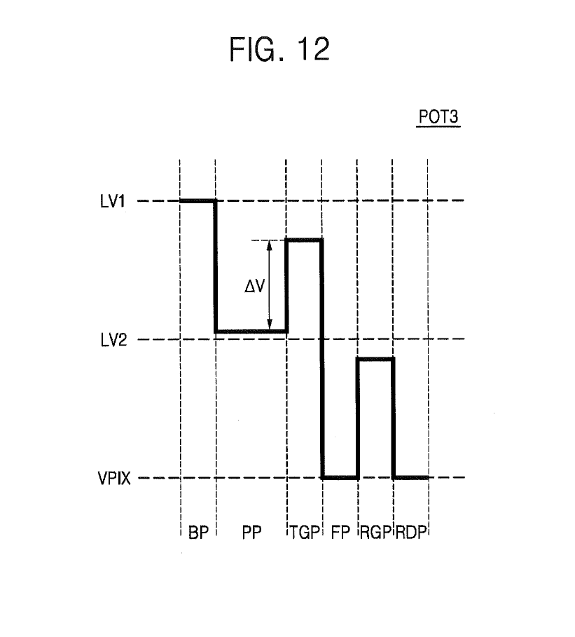

FIG. 12 shows a third potential distribution POT3, according to an example embodiment. As shown in FIG. 12, when the bulk control signal BCS is at the first level LV1, the transfer control signal TG is at the low level and/or the reference voltage level, and the reset control signal RS is at the low level and/or the reference voltage level. In various embodiments, the third potential distribution POT3 shows a potential distribution in periods between time points t3 and t4, between time points t5 and t6, between time points t10 and t11, and between time points t12 and t13 in FIG. 8 and periods between time points t3 and t4, between time points t5 and t6, between time points t10 and t11, and between time points t12 and t13 in FIG. 9.

The bulk potential BP, the photo diode potential PP, the transfer transistor gate potential TGP, the floating diffusion node potential FP, and the reset transistor drain potential RDP remain the same as the second potential distribution POT2. Since the reset control signal RS transits to the low level and/or the reference voltage level, the reset transistor gate potential RGP is at a level slightly higher than the second level LV2.

As shown in FIGS. 11 and 12, when the bulk potential BP, the photo diode potential PP, and the transfer transistor gate potential TGP are changed by changing the level of the bulk control signal BCS to the first level LV1 and then the reset control signal RS is changed to the low level and/or the reference voltage level, the difference between the photo diode potential PP and the floating diffusion node potential FP is maximized. When the bulk potential BP, the photo diode potential PP, and the transfer transistor gate potential TGP are changed after the floating diffusion node FD enters the floating state since the reset control signal RS is changed to the low level and/or the reference voltage level, the transfer transistor gate potential TGP decreases due to the coupling effect between the gate of the transfer transistor TX and the floating diffusion node FD and the floating diffusion node potential FP also decreases at this time.

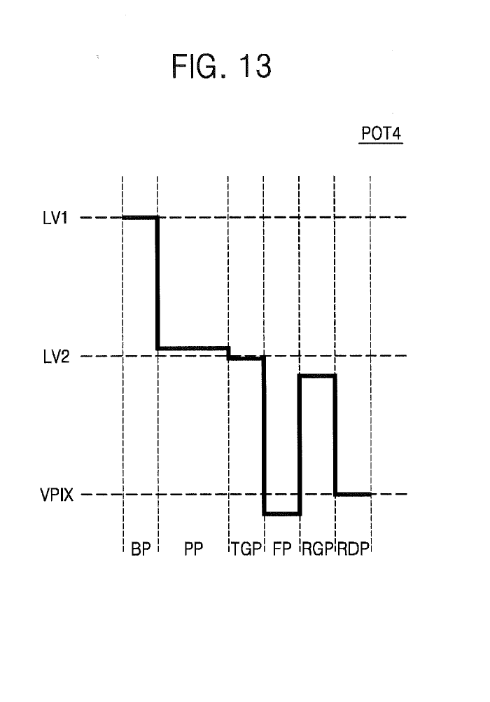

FIG. 13 shows a fourth potential distribution POT4, according to an example embodiment. As shown in FIG. 13, when the bulk control signal BCS is at the first level LV1, the transfer control signal TG is at the high level, and the reset control signal RS is at the low level and/or the reference voltage level. In various embodiments, the fourth potential distribution POT4 shows a potential distribution in periods between time points t4 and t5 and between time points t11 and t12 in FIG. 8 and periods between time points t4 and t5 and between time points t11 and t12 in FIG. 9. The bulk potential BP, the photo diode potential PP, the reset transistor gate potential RGP, and the reset transistor drain potential RDP remain the same as the third potential distribution POT3.

Since the transfer control signal TG transits to the high level, the transfer transistor gate potential TGP becomes slightly higher than the photo diode potential PP. As the transfer transistor gate potential TGP increases, photocharges accumulated at the photo diode PD are transferred to the floating diffusion node FD. At this time, since the difference between the photo diode potential PP and the floating diffusion node potential FP has already been increased, the photocharges are transferred more efficiently.

In addition, when the transfer transistor gate potential TGP increases due to the coupling effect between the gate of the transfer transistor TX and the floating diffusion node FD, there occurs FD boosting in which the floating diffusion node potential FP also increases. The floating diffusion node potential FP becomes higher than the pixel voltage VPIX due to the FD boosting, and thus the difference between the photo diode potential PP and the floating diffusion node potential FP gets greater.

When the first potential distribution POT1 is changed into the second potential distribution POT2 (e.g., at time point t2 in FIG. 8), the potential of the photo diode PD may be considered “changed”. When the second potential distribution POT2 is changed into the first potential distribution POT1 (e.g., at time point t7 in FIG. 8), the potential of the photo diode PD may be considered “recovered”.

Consequently, according to an example embodiment, an image sensor improves the characteristic of a pixel by controlling the voltage level of a bulk of the pixel.

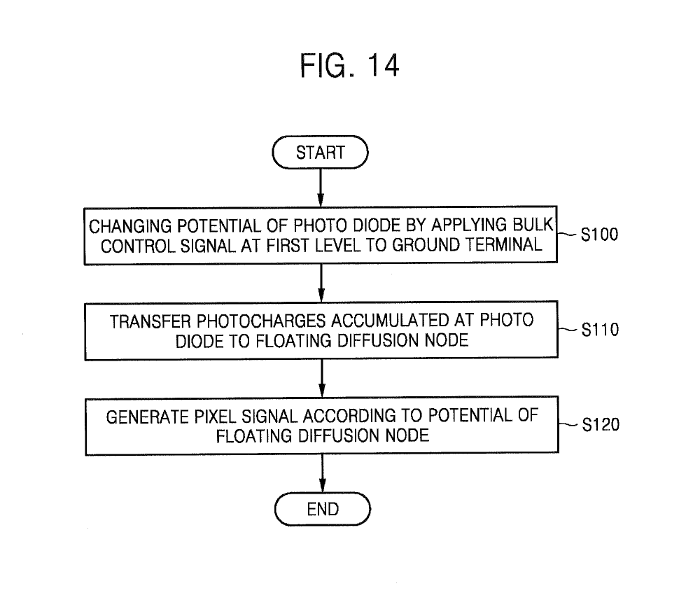

FIG. 14 is a flowchart of a method of operating an image sensor according to an example embodiment. The method of operating an image sensor, as shown in FIG. 14, may be performed by the image sensor according to the example embodiments shown by FIGS. 1 through 5A and FIGS. 8 through 13.

As shown in operation S100, a potential of the photo diode is changed by applying the bulk control signal at a first voltage level to the ground terminal. According to various embodiments, the reset transistor RX included in the pixel 112a may reset the floating diffusion node FD to the pixel voltage VPIX according to the reset control signal RS. In various embodiments, the floating diffusion node FD may be maintained at the pixel voltage VPIX as shown in the first potential distribution POT1.

As shown in operation S110, transfer photocharges are accumulated at the photo diode to the floating diffusion node. According to various embodiments, the row driver 160 may turn on the transfer transistor TX by applying the transfer control signal TG at the high level to the pixel 112a. As a result, photocharges accumulated at the photo diode PD may be transferred to the floating diffusion node FD. In various embodiments, when the transfer transistor gate potential TGP is increased as in the fourth potential distribution POT4 after the floating diffusion node FD enters the floating state as in the third potential distribution POT 3, the photocharges accumulated at the photo diode PD may be transferred to the floating diffusion node FD

As shown in operation S120, a pixel signal is generated according to the potential of the floating diffusion node. According to various embodiments, the row driver 160 may apply the selection control signal SEL at the high level to the pixel 112a, so that a pixel signal is generated according to the floating diffusion node potential FP and output to the column line COL.

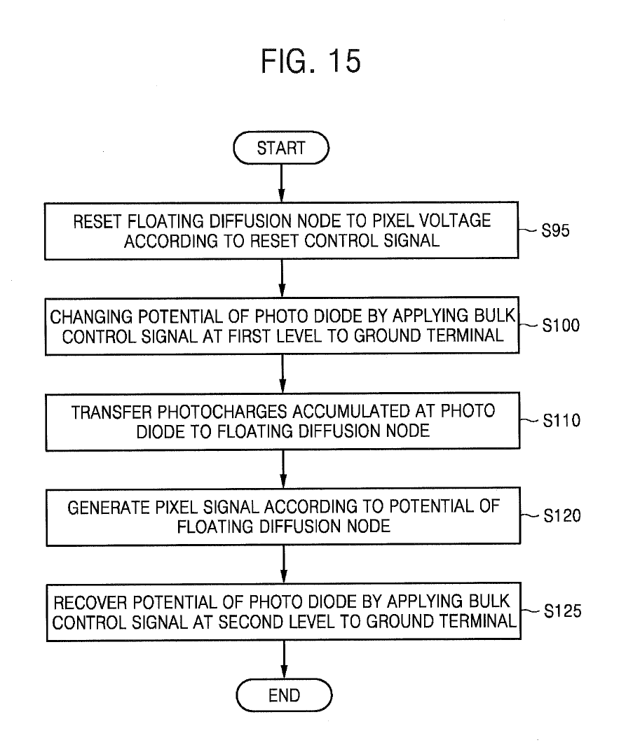

FIG. 15 is a flowchart of a method of operating an image sensor according to an example embodiment. The method of operating an image sensor, as shown in FIG. 14, may be performed by the image sensor according to the example embodiments shown by FIGS. 1 through 5A and FIGS. 8 through 13.

As shown in operation S95, the floating diffusion node is reset to a pixel voltage according to a reset control signal. Referring to FIGS. 1 through 5A and FIGS. 8 through 13, the reset transistor RX included in the pixel 112a may reset the floating diffusion node FD to the pixel voltage VPIX according to the reset control signal RS. In various embodiments, the floating diffusion node FD may be maintained at the pixel voltage VPIX as shown in the first potential distribution POT1.

As shown in S100, a potential of the photo diode is changed by applying the hulk control signal at a first voltage level to the ground terminal In a state where the floating diffusion node FD is maintained at the pixel voltage VPIX, the row driver 160 may apply the bulk control signal BCS at the first level LV1 to the ground terminal 434, so that the potential of the photo diode PD is changed. In various embodiments, the photo diode potential PP is decreased by changing the bulk potential BP while the floating diffusion node FD is maintained at the pixel voltage VPIX, as shown in the second potential distribution POT2. A period (e.g., t2 to t7 or t8 to t15) in which the potential of the photo diode PD is changed includes a period (e.g., t3 to t6 or t10 to t13) in which the reset control signal RS is at the low level and/or the reference voltage level.

As shown in operation S110, transfer photocharges are accumulated at the photo diode to the floating diffusion node. The row driver 160 may turn on the transfer transistor TX by applying the transfer control signal TG at the high level to the pixel 112a. As a result, photocharges accumulated at the photo diode PD may be transferred to the floating diffusion node FD. In various embodiments, when the transfer transistor gate potential TGP is increased as in the fourth potential distribution POT4 after the floating diffusion node FD enters the floating state as in the third potential distribution POT 3, the photocharges accumulated at the photo diode PD may be transferred to the floating diffusion node FD.

As shown in operation S120, a pixel signal is generated according to the potential of the floating diffusion node. The row driver 160 may apply the selection control signal SEL at the high level to the pixel 112a, so that a pixel signal is generated according to the floating diffusion node potential FP and output to the column line COL.

As shown in operation S125, the potential of the photo diode is recovered by applying the bulk control signal at a second voltage level to the ground terminal. The row driver 160 may apply the bulk control signal BCS at the second level LV2 to the ground terminal 434, so that the photo diode potential PP is recovered. In various embodiments, after the photocharge transfer to the floating diffusion node FD is completed and the reset transistor RX is turned on, the photo diode potential PP may be recovered to the second level LV2.

As described above with reference to FIGS. 2 through 4, the first or second level LV1 or LV2 of the bulk control signal BCS may be the same among all pixels included in the pixel array 110, may be different from row to row, or may be different from pixel to pixel.

The example embodiments can also be embodied as computer-readable codes on a computer-readable medium. The computer-readable recording medium is any data storage device that can store data as a program which can be thereafter read by a computer system. Examples of the computer-readable recording medium include read-only memory (ROM), random-access memory (RAM), CD-ROMs, magnetic tapes, floppy disks, and optical data storage devices.

The computer-readable recording medium can also be distributed over network coupled computer systems so that the computer-readable code is stored and executed in a distributed fashion. Also, functional programs, codes, and code segments to accomplish the example embodiments can be easily construed by programmers.

As described above, according to example embodiments, an image sensor controls the voltage level of a bulk of a pixel, thereby improving the characteristic of the pixel.

While the example embodiments have been particularly shown and described with reference to exemplary embodiments thereof, it will be understood by those of ordinary skill in the art that various changes in forms and details may be made therein without departing from the spirit and scope of the embodiments as defined by the following claims.

1-10. (canceled)

11. An image sensor comprising:
a plurality of pixels, each one of the plurality of pixels including,
a photo diode configured to accumulate photocharges, the photocharges being generated according to incident light, and
a ground terminal configured to receive a hulk control signal at a first voltage level, the bulk control signal being used to change a potential of the photo diode.

12. The image sensor of claim 11, wherein each one of the plurality of pixels further comprises:
a transfer transistor configured to transfer the photocharges accumulated at the photo diode to a floating diffusion node;
a drive transistor configured to generate a pixel signal according to a potential of the floating diffusion node; and
a deep trench isolation (DTI) region configured to electrically isolate each one of the plurality of pixels from adjacent ones of the plurality of pixels.

13. The image sensor of claim 12, the first voltage level is not 0 V.

14. The image sensor of claim 11, wherein the ground terminal receives the bulk control signal at a second voltage level to recover the potential of the photo diode.

15. The image sensor of claim 14, wherein the second voltage level is 0 V.

16. The image sensor of claim 11, wherein each of the pixels further comprises:
a reset transistor configured to reset a floating diffusion node to a pixel voltage according to a reset control signal, the reset control signal is at a reference voltage level when a period in which the bulk control signal is at the first voltage level.

17. The image sensor of claim 11, wherein the first voltage level is a negative voltage level.

18. The image sensor of claim 11, wherein each of the plurality of pixels receives the same bulk control signal.

19. The image sensor of claim 11, wherein the plurality of pixels are arranged in a matrix including a plurality of rows and a plurality of columns, and
each of the plurality of rows receives the bulk control signal at the first voltage level during a different time period.

20. The image sensor of claim 11, wherein each of the pixels receives the bulk control signal at the first voltage level during a different time period.

21. An image sensor comprising:
a plurality of pixels, each of the plurality of pixels including,
a photo diode configured to accumulate photocharges generated according to incident light, and,
a ground terminal;
a row driver configured to,
generate a bulk control signal for each of the plurality of pixels, and
transfer the bulk control signal to the ground terminal of each of the plurality of pixels; and
a readout block configured to process a pixel signal output from each of the plurality of pixels,
each of the plurality of pixels generates the pixel signal corresponding to the photocharges accumulated at the photo diode having a potential changing according to the bulk control signal at a first voltage level.

22. The image sensor of claim 21, wherein the first voltage level is not 0 V.

23. The image sensor of claim 21, wherein each of the plurality of pixels further comprise:
a deep trench isolation (DTI) region configured to electrically isolate each of the plurality of pixels from adjacent ones of the plurality of pixels.

24. The image sensor of claim 21, wherein each pixel receives the bulk control signal at a second voltage level and recovers the potential of the photo diode and the second voltage level is 0 V.

25. The image sensor of claim 21, wherein each of the plurality of pixels further comprise:
a floating diffusion node; and
a reset transistor configured to reset the floating diffusion node to a pixel voltage according to a reset control signal, the reset control being at a reference voltage level when a period in which the bulk control signal is at the first.

26. The image sensor of claim 21, wherein the first voltage level is a negative voltage level.

27. The image sensor of claim 21, wherein each of the plurality of pixels receives the same hulk control signal at the first voltage level.

28. The image sensor of claim 21, wherein the plurality of pixels are arranged in a matrix including a plurality of rows and a plurality of columns, and
each of the plurality of rows receives the bulk control signal at the first voltage level during a different time period.

29. The image sensor of claim 21, wherein each pixel receives the bulk control signal at the first voltage level during a different time period.

30. An image processing system comprising:
an image sensor including a plurality of pixels, each of the plurality of pixels including a photo diode configured to,
accumulate photocharges generated according to incident light, and
read out a pixel signal that is output from each of the plurality of pixels:
each of the plurality of pixels including,
a ground terminal configured to receive a bulk control signal at a first voltage level to change a potential of the photo diode;
a transfer transistor configured to transfer the photocharges accumulated at the photo diode to a floating diffusion node; and
a drive transistor configured to generate the pixel signal according to a potential of the floating diffusion node; and
an image signal processor configured to,
process the pixel signal, and
generate image data.
